(19) United States
(12) Patent Application Publication
(10) Pub. No.: US 2026/0196260 A1
(43) Pub. Date: Jul. 9, 2026

(54) COLD MEMORY TRACKING FOR POWER SAVING ON CXL DEVICES

(71) Applicant: Micron Technology, Inc., Boise, ID (US)

(72) Inventors: Massimiliano Patriarca, Milano, MI (US); Graziano Mirichigni, Vimercate (IT); Alessandro Orlando, Milan (IT)

(21) Appl. No.: 19/407,737

(22) Filed: Dec. 3, 2025

Related U.S. Application Data
(60) Provisional application No. 63/743,067, filed on Jan. 8, 2025.

(51) Int. Cl. G11C 11/4074; G11C 11/4076

(52) U.S. Cl. CPC G11C 11/4074; G11C 11/4076; G11C 2207/2227

(57) ABSTRACT

Apparatus and methods are disclosed, including detecting when time from a last access to a memory rank of the memory system is greater than a first rank-access threshold time, placing the memory rank in a first low power mode in response to the detecting, wherein the memory rank consumes lower energy in the first low power mode than a normal operating mode, detecting when the time from a last access to a memory rank is greater than a second rank-access threshold time, and placing the memory rank in a second low power mode, wherein the memory rank consumes lower energy in the second low power mode than in the first low power mode.

### PRIORITY APPLICATION

This application claims the benefit of priority to U.S. Provisional Application Ser. No. 63/743,067, filed Jan. 8, 2025, which is incorporated herein by reference in its entirety.

### BACKGROUND

Memory devices are semiconductor circuits that provide electronic storage of data for a host system (e.g., a computer or other electronic device). Memory devices may be volatile or non-volatile. Volatile memory requires power to maintain data, and includes devices such as random-access memory (RAM), static random-access memory (SRAM), dynamic random-access memory (DRAM), or synchronous dynamic random-access memory (SDRAM), among others.

Host systems typically include a host processor, a first amount of main memory (e.g., often volatile memory, such as DRAM) to support the host processor, and one or more memory systems (e.g., often non-volatile memory, such as flash memory, and may include volatile memory) that provide additional storage to retain data in addition to or separate from the main memory.

A memory system can include a memory controller and one or more memory devices, including a number of dies or logical units (LUNs). In certain examples, each die can include a number of memory arrays and peripheral circuitry thereon, such as die logic or a die processor. A memory rank can include multiple memory dies. A memory channel can include multiple memory ranks. The memory controller can include interface circuitry configured to communicate with a host device (e.g., the host processor or interface circuitry) through a communication interface (e.g., a bidirectional parallel or serial communication interface). The memory controller can receive commands or operations from the host system in association with memory operations or instructions, such as read or write operations to transfer data (e.g., user data and associated integrity data, such as error data or address data, etc.) between the memory devices and the host device, erase operations to erase data from the memory devices, perform drive management operations (e.g., data migration, garbage collection, block retirement), etc.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a diagram of an example computing system including a host device and a memory system.

FIG. 2 is a block diagram of portions of an example of a memory system.

FIG. 3 is a flow diagram of an example of a method of operating a memory system.

FIG. 4 is a diagram of another example computing system.

FIG. 5 is an illustration of a mapping of memory of a storage system.

FIG. 6 illustrates an example block diagram of a host system.

### DETAILED DESCRIPTION

Software (e.g., programs), instructions, operating systems (OS), and other data are typically stored on storage systems and accessed for use by a host processor. Main memory (e.g., RAM) is typically faster, more expensive, and a different type of memory device (e.g., volatile) than a majority of the memory devices of the storage system (e.g., non-volatile, such as an SSD, etc.). In addition to the main memory, host systems can include different levels of volatile memory, such as a group of static memory (e.g., a cache, often SRAM), often faster than the main memory, in certain examples, configured to operate at speeds close to or exceeding the speed of the host processor, but with lower density and higher cost. Systems can include high speed, low latency compute express link (CXL) compatible memory. The CXL compatible memory provides a high capacity link between processors and the memory system.

The present inventors have recognized, among other things, that all memory of a memory system is not utilized equally. Reducing power on sections of memory that are not being utilized can improve the energy efficiency of the memory system.

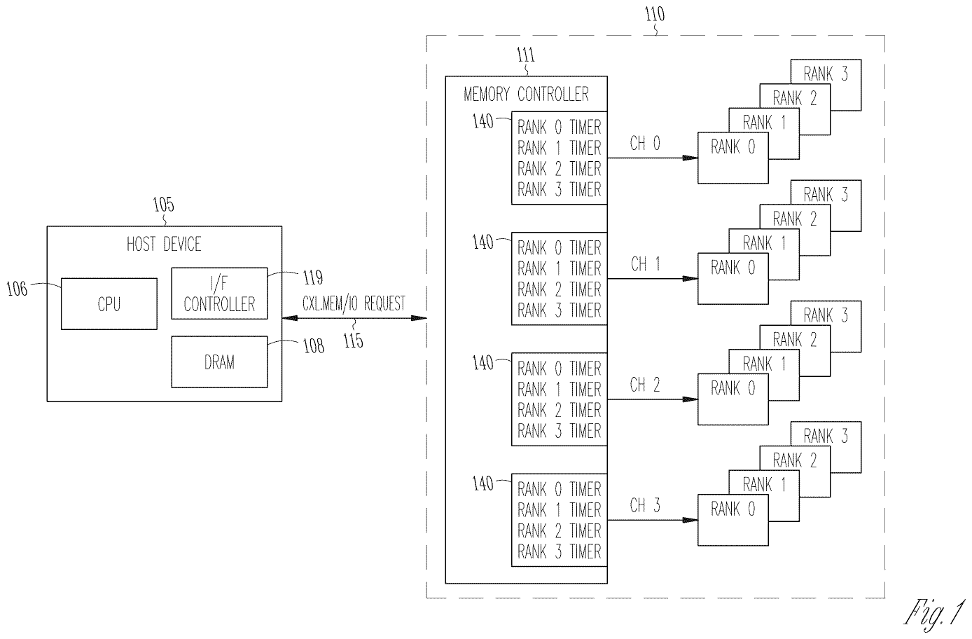

FIG. 1 illustrates an example computing system (e.g., a host system) 100 including a host device 105 and a memory system 110 that includes a storage system. The storage system includes a memory controller 111 and multiple memory channels (Ch0, . . . Ch3) that each include multiple memory ranks. The memory channels may comply to double data rate (DDR) or low power DDR (LPDDR) standards. The host device 105 and the memory system 110 communicate over a communication interface 115 (e.g., a bidirectional parallel or serial communication interface). The interface 115 may be CXL-compatible. The host device 105 can include a host processor 106 (e.g., a host central processing unit (CPU) or other processor or processing device) or other host circuitry (e.g., a memory management unit (MMU), interface circuitry, assessment circuitry, etc.). In certain examples, the host device 105 can include a main memory that includes DRAM 108 to support operation of the host processor 106. The memory controller 111 of the memory system 110 includes processing circuitry (e.g., a processor or processing device, an application specific integrated circuit (ASIC), or programmable gate array (PGA)) to perform the functions described for the memory controller 111. The memory ranks of the memory system 110 can include multiple memory devices (e.g., multiple DRAM devices). The memory system 110 can include a high-capacity link between the memory controller 111 and the memory ranks. To access the memory ranks, the host device 105 may send instructions to a communication interface (I/F) controller (119) that routes a memory request to the memory controller 111.

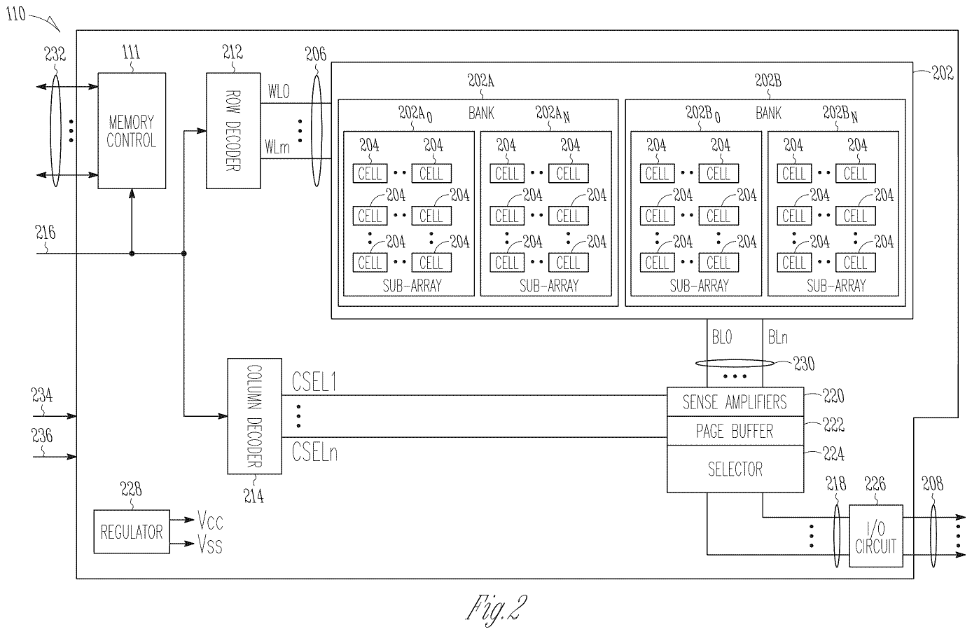

FIG. 2 illustrates an example block diagram of portions of a memory system 110 including a memory array 202 having a plurality of memory cells 204, and one or more circuits or components to provide communication with, or perform one or more memory operations on, the memory array 202. Although shown with a single memory array 202, in other examples, one or more additional memory arrays, dies, or LUNs can be included herein. The memory system 110 can include a row decoder 212, a column decoder 214, sense amplifiers 220, a page buffer 222, a selector 224, an input/output (I/O) circuit 226, and a memory controller 111.

The memory cells 204 of the memory array 202 can be arranged in banks, such as first and second banks 202A, 202B. Each sector can include sub-sections or sub-arrays. For example, the first bank 202A can include first and second sub-arrays 202A₀, 202Aₙ, and the second bank 202B can include first and second sub-arrays 202B₀, 202Bₙ. Each sub-array can include a number of physical pages, each page including a number of memory cells 204. Although illustrated herein as having two banks, each block having two sub-arrays, and each sub-array having a number of memory cells 204, in other examples, the memory array 202 can include more or fewer banks, sub-arrays, memory cells, etc. In other examples, the memory cells 204 can be arranged in a number of rows, columns, pages, sub-arrays, banks, etc., and accessed using, for example, access lines 206, first data lines 230, or one or more select gates, source lines, etc.

The memory controller 111 can control memory operations of the memory system 110 according to one or more signals or instructions received on control lines 232, including, for example, one or more clock signals or control signals that indicate a desired operation (e.g., write, read, erase, etc.), or address signals (A0-AX) received on one or more address lines 216. One or more devices external to the memory system 110 can control the values of the control signals on the control lines 232, or the address signals on the address line 216. Examples of devices external to the memory system 110 can include, but are not limited to, a host, a memory controller, a processor, or one or more circuits or components not illustrated in FIG. 2.

The memory system 110 can use access lines 206 and first data lines 230 to transfer data to (e.g., write or erase) or from (e.g., read) one or more of the memory cells 204. The row decoder 212 and the column decoder 214 can receive and decode the address signals (A0-AX) from the address line 216, can determine which of the memory cells 204 are to be accessed, and can provide signals to one or more of the access lines 206 (e.g., one or more of a plurality of word lines (WL0-WLm)) or the first data lines 230 (e.g., one or more of a plurality of bit lines (BL0-BLn)), such as described above.

The memory system 110 can include sense circuitry, such as the sense amplifiers 220, configured to determine the values of data on (e.g., read), or to determine the values of data to be written to, the memory cells 204 using the first data lines 230. For example, in a selected string of memory cells 204, one or more of the sense amplifiers 220 can read a logic level in the selected memory cell 204 in response to a read current flowing in the memory array 202 through the selected string to the data lines 230.

One or more devices external to the memory system 110 can communicate with the memory system 110 using the I/O lines (DQ0-DQN) 208, address lines 216 (A0-AX), or control lines 232. The input/output (I/O) circuit 226 can transfer values of data in or out of the memory system 110, such as in or out of the page buffer 222 or the memory array 202, using the I/O lines 208, according to, for example, the control lines 232 and address lines 216. The page buffer 222 can store data received from the one or more devices external to the memory system 110 before the data is programmed into relevant portions of the memory array 202, or can store data read from the memory array 202 before the data is transmitted to the one or more devices external to the memory system 110.

The column decoder 214 can receive and decode address signals (A0-AX) into one or more column select signals (CSEL1-CSELn). The selector 224 (e.g., a select circuit) can receive the column select signals (CSEL1-CSELn) and select data in the page buffer 222 representing values of data to be read from or to be programmed into memory cells 204. Selected data can be transferred between the page buffer 222 and the I/O circuit 226 using second data lines 218.

The memory controller 111 can receive positive and negative supply signals, such as a supply voltage (Vcc) 234 and a negative supply (Vss) 236 (e.g., a ground potential), from an external source or supply (e.g., an internal or external battery, an AC-to-DC converter, etc.). In certain examples, the memory controller 111 can include a regulator 228 to internally provide positive or negative supply signals.

Returning to the example system 100 of FIG. 1, to access the memory devices 112 the host device 105 may send instructions to an I/F controller 119. The I/F controller 119 will route tiered memory requests to the memory controller 111. The memory controller 111 can include, among other things, processing circuitry or firmware, such as a number of components or integrated circuits. For example, the memory controller 111 can include one or more memory controllers, circuits, or components configured to control access across the memory array and to provide a translation layer between the host device 105 and the memory system 110.

The example of FIG. 1 shows only 4 channels and sixteen ranks for simplicity of the diagram and an actual system can include many more channels and ranks, and the ranks can include many memory components or memory dies. It is desirable to improve the power efficiency of the memory systems.

To improve the power efficiency of the memory system 100 the memory controller 111 changes the state of a memory rank if the memory rank is not receiving memory requests, this can be referred to as the memory rank being “cold.” To detect cold memory ranks, the memory system 110 includes memory rank timers 140. The memory system 110 may have a memory rank timer 140 for each memory rank. The memory rank timers 140 may be implemented by processing circuitry of the memory controller 111 or may be discrete timing circuits. The memory controller 111 can detect that a memory rank is cold when the memory rank timer expires.

The memory rank timer 140 for a memory rank may be reset each time the memory rank is accessed. Some examples of memory rank accesses that reset the memory rank timer include, among other things, read requests, write requests, activate commands, and pre-charge commands. When a memory rank timer expires, it indicates that the corresponding memory rank is not being accessed and is cold. Because the memory rank is not accessed often, the memory controller 111 can change the operating mode of the memory rank from a normal operating mode to a lower power mode that consumes less power than the normal operating mode. However, it takes time to restore a memory rank from a low power state back to the normal operating state. The memory controller 111 is able to place the memory rank in different low power states based on how long it has been since the last access to the memory rank (or how cold the memory rank is).

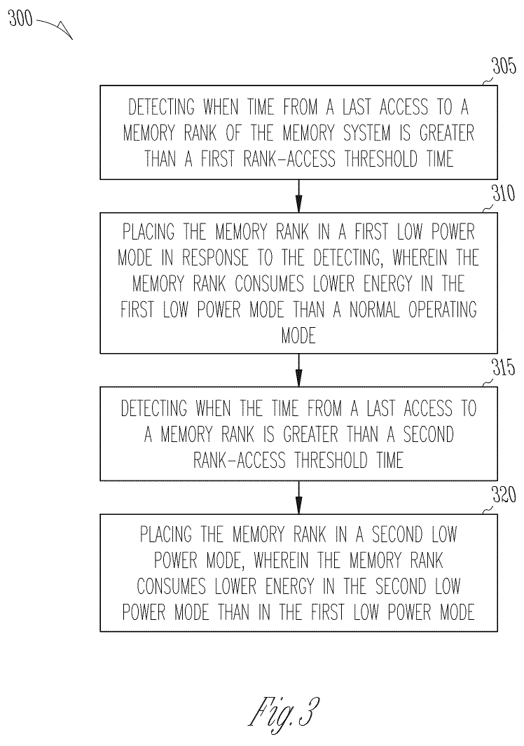

FIG. 3 is a flow diagram of an example of a method 300 of operating a memory system (e.g., memory system 110 in FIG. 1). The memory controller 111 of the memory system 110 detects when memory ranks are cold. At block 305, the memory controller 111 detects when the time from the last access to a memory rank of the memory system is greater than a specified (e.g., programmed) first rank-access threshold time. The memory controller 111 may detect that the time from the last access is longer than the first rank-access threshold time when the memory rank timer for the memory rank exceeds the first rank-access threshold time before it is reset by a memory access to the memory rank.

At block 310, the memory controller 111 places the memory rank in a first low power mode in response to detecting that the time from the last access to the memory rank exceeds the first rank-access time threshold. In the first low power mode, the memory rank consumes lower energy than the normal operating mode of the memory rank. The first low power mode may be a self-refresh power down state. In the self-refresh power down state, the memory rank retains data without an external refresh command. The memory device or devices of the memory rank include a built-in timer for the self-refresh operation. The self-refresh power down state may include the self-refresh power down operation defined in JEDEC standard No. 209-5C.

At block 315, the memory controller 111 detects when the time from the last access to a memory rank of the memory system is greater than a second rank-access threshold time. The second rank-access threshold time is longer than the first rank-access threshold time. The memory controller 111 may detect that the time from the last access is longer than the second rank-access threshold time when the memory rank timer for the memory rank exceeds the second rank-access threshold time before it is reset by a memory access to the memory rank.

At block 320, the memory controller 111 places the memory rank in a second low power mode in response to detecting that the time from the last access to the memory rank exceeds the second time threshold. In the second low power mode, the memory rank consumes lower energy than in the first low power mode. The second low power mode may be a deep sleep state. The memory device or devices of the memory bank are set to a state of low current consumption in the deep sleep state. The deep sleep state may include the deep sleep operation defined in JEDEC standard No. 209-5C.

If the memory rank is accessed after the first rank-access threshold time but before the second rank-access threshold time, the memory controller 111 returns the entire memory rank to normal operation without entering the second low power mode. If the memory rank is accessed after the second rank-access threshold time, the memory controller 111 returns the entire memory rank to the normal operating mode from the second low power mode. Thus, the memory ranks of the storage system may be in any of the three modes, with a first portion of the cold memory ranks being in the first low power mode, a second portion of the cold memory ranks being in the second low power mode, and the non-cold memory ranks being in a normal operating mode.

It may take longer for a memory rank to recover from the second low power mode (e.g., a deep sleep state) than the first low power mode (e.g., a self-refresh state). Having the multiple rank-access time thresholds results in placing the “coldest” memory ranks in the second low power mode, which may reduce the impact of low power modes on the performance of the memory system.

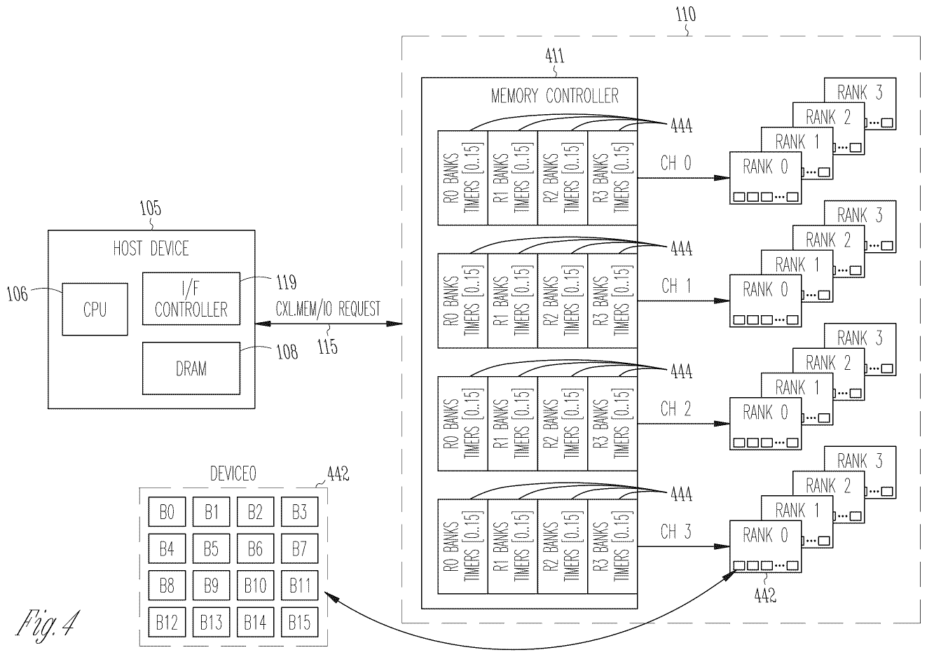

FIG. 4 illustrates another example computing system (e.g., a host system) 100 including a host device 105 and a memory system 110 that includes a storage system. The memory system 110 includes a memory controller 411 and a storage system that includes multiple memory ranks. FIG. 4 shows that the memory ranks each include one or more memory devices 442 or memory components. Each memory device 442 includes a number of memory banks. In the examples of FIG. 4, each memory device includes sixteen memory banks but the memory devices 442 may include other numbers of memory banks (e.g., 32 memory banks). Each bank is designated with a number (e.g., B0, B1, . . . B15 if there are 16 memory banks).

The memory controller 411 monitors for cold memory banks and changes the state of cold memory banks to a lower power mode. Thus, the memory controller 411 monitors for cold memory with a finer level of granularity than the memory rank level.

The memory controller 111 places the cold memory bank in different low power states based on how long it has been since the last access to the memory bank. The memory controller 111 detects when the time from the last access to the memory bank is greater than a specified first bank-access threshold time, and places the memory bank in the first low power mode (e.g., the self-refresh power down state) in response to detecting that the first bank-access threshold time is exceeded. The memory controller 111 detects when the time from the last access to the memory bank is greater than a specified second bank-access threshold time, and places the memory bank in the second low power mode (e.g., the deep sleep state) in response to detecting that the second bank-access threshold time is exceeded.

To detect cold memory banks, the memory system 110 includes memory bank timers 444. The memory system 110 may have a memory bank timer 444 for each memory bank of each memory rank. The memory bank timer 444 for a memory rank may be reset each time the memory rank is accessed. The memory bank timers 444 may be implemented by processing circuitry of the memory controller 111 or may be discrete timing circuits. The memory bank timers 444 are reset (e.g., initialized to a count of zero) when the memory system 110 is initialized. The memory bank timers 444 begin counting after reset and are again reset when the corresponding memory bank for the timer is accessed. The memory controller 411 may detect that a memory bank is cold when the corresponding the memory bank timer 444 expires or reaches the specified bank-access threshold time.

The memory ranks of the storage system may have multiple memory devices. According to some examples, when a particular memory bank of a memory device of a memory rank is accessed, the same memory bank of all the memory devices of the memory rank is accessed in parallel. For example, if a memory request accesses memory bank B0 of memory rank 0, memory bank B0 of all the memory devices of memory rank 0 are accessed in parallel. When the memory bank 0 of the memory rank 0 is cold, the memory controller 411 may place all the B0 memory banks of memory rank 0 to the same low power mode. For example, when the time from the last access to the B0 memory banks of the memory devices of the memory rank is greater than the first bank-access threshold time, the memory controller 411 places all of the B0 memory banks in the first low power mode. When the time from the last access to the B0 memory banks of the memory devices of the memory rank is greater than the second bank-access threshold time, the memory controller 411 places all of the B0 memory banks in the second low power mode. The memory controller 411 returns all the B0 memory banks to the normal operating mode when the B0 banks are accessed.

The memory devices of a memory rank are configured (e.g., through firmware or hardware design) for power management at the memory bank level so that a given time, some memory banks of the memory rank may be in the normal operating mode, some memory banks may be in the first low power mode, and some memory banks may be in the second low power mode. The memory controller 411 may be configured to produce a mapping of which memory banks of the multiple memory banks are operating in the self-refresh power down state, in the deep sleep state, and in a normal operating state.

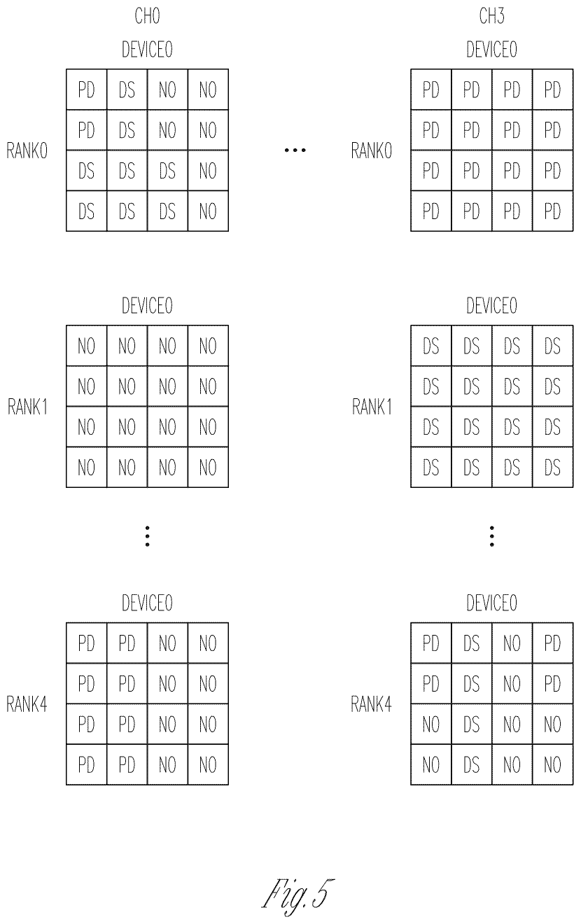

FIG. 5 is an illustration of a map of the storage system of FIG. 4. FIG. 5 shows memory banks of the memory devices 442 placed in low power modes and memory ranks placed in low power modes. The devices, systems, and methods described herein enable tracking of one or both of cold memory ranks and cold memory banks at the memory controller level of a computer system. Using the cold tracking capability, the memory controller can implement power saving strategies for the storage system.

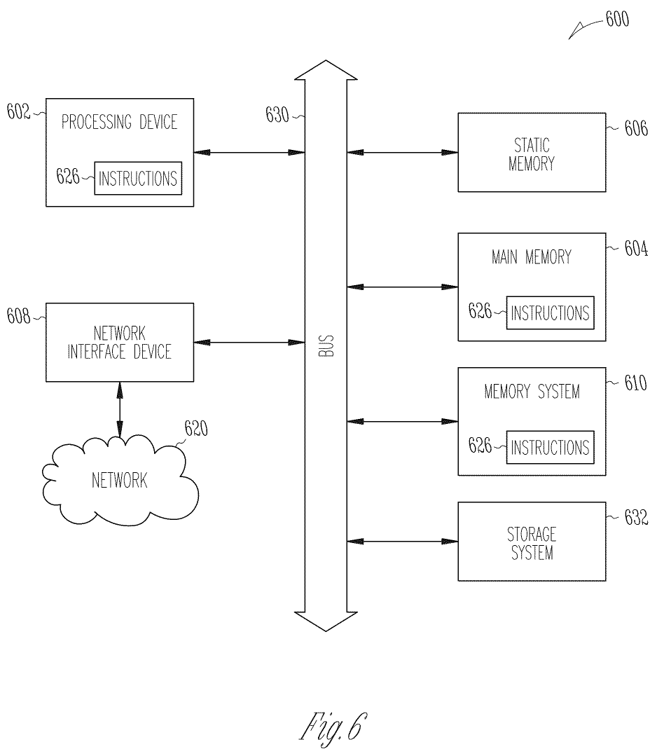

FIG. 6 illustrates a block diagram of an example machine 600 (e.g., a host system) upon which any one or more of the techniques (e.g., methodologies) discussed herein may perform. In alternative embodiments, the machine 600 may operate as a standalone device or may be connected (e.g., networked) to other machines. In a networked deployment, the machine 600 may operate in the capacity of a server machine, a client machine, or both in server-client network environments. In an example, the machine 600 may act as a peer machine in peer-to-peer (P2P) (or other distributed) network environment. The machine 600 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine 600 (e.g., computer system, a host system, etc.) may include a processing device 602 (e.g., a hardware processor, a central processing unit (CPU), a graphics processing unit (GPU), a hardware processor core, or any combination thereof, etc.), a main memory 604 (e.g., read-only memory (ROM), dynamic random-access memory (DRAM) such as synchronous DRAM (SDRAM) or Rambus DRAM (RDRAM), etc.), a static memory 606 (e.g., static random-access memory (SRAM), etc.), a memory system 610, and a storage system 632, some or all of which may communicate with each other via a communication interface (e.g., a bus) 630.

The processing device 602 can represent one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 602 can also be one or more special-purpose processing devices such as an application specific integrated circuit (ASIC), a field programmable gate array (FPGA), a digital signal processor (DSP), network processor, or the like. The processing device 602 can be configured to execute instructions 626 for performing the operations and steps discussed herein. The computer system can further include a network interface device 608 to communicate over a network 620.

The memory system 610 can include a machine-readable storage medium (also known as a computer-readable medium) on which is stored one or more sets of instructions 626 or software embodying any one or more of the methodologies or functions described herein. The instructions 626 can also reside, completely or at least partially, within the main memory 604 or within the processing device 602 during execution thereof by the computer system, the main memory 604 and the processing device 602 also constituting machine-readable storage media.

The term “machine-readable storage medium” should be taken to include a single medium or multiple media that store the one or more sets of instructions, or any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media. In an example, a massed machine-readable medium comprises a machine-readable medium with a plurality of particles having invariant (e.g., rest) mass. Accordingly, massed machine-readable media are not transitory propagating signals. Specific examples of massed machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The machine 600 may further include a display unit, an alphanumeric input device (e.g., a keyboard), and a user interface (UI) navigation device (e.g., a mouse). In an example, one or more of the display units, the input device, or the UI navigation device may be a touch screen display. The machine may include a signal generation device (e.g., a speaker), or one or more sensors, such as a global positioning system (GPS) sensor, compass, accelerometer, or one or more other sensors. The machine 600 may include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The instructions 626 (e.g., software, programs, an operating system (OS), etc.) or other data stored on the storage system 632 can be accessed by the main memory 604 for use by the processing device 602. The main memory 604 (e.g., DRAM) is typically fast, but volatile, and thus a different type of storage than the storage system 632 (e.g., an SSD), which is suitable for long-term storage, including while in an “off” condition. The instructions 626 or data in use by a user or the machine 600 are typically loaded in the main memory 604 for use by the processing device 602. When the main memory 604 is full, virtual space from the memory system 610 can be allocated to supplement the main memory 604; however, because the memory system 610 device is typically slower than the main memory 604, and write speeds are typically at least twice as slow as read speeds, use of virtual memory can greatly reduce user experience due to storage system latency (in contrast to the main memory 604, e.g., DRAM). Further, use of the storage system 632 for virtual memory can greatly reduce the usable lifespan of the storage system 632.

The instructions 626 may further be transmitted or received over a network 620 using a transmission medium via the network interface device 608 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, the network interface device 608 may include one or more physical jacks (e.g., Ethernet, coaxial, or phone jacks) or one or more antennas to connect to the network 620. In an example, the network interface device 608 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 600, and includes digital or analog communications signals or other intangible medium to facilitate communication of such software.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The term “horizontal” as used in this document is defined as a plane parallel to the conventional plane or surface of a substrate, such as that underlying a wafer or die, regardless of the actual orientation of the substrate at any point in time. The term “vertical” refers to a direction perpendicular to the horizontal as defined above. Prepositions, such as “on,” “over,” and “under” are defined with respect to the conventional plane or surface being on the top or exposed surface of the substrate, regardless of the orientation of the substrate; and while “on” is intended to suggest a direct contact of one structure relative to another structure which it lies “on” in the absence of an express indication to the contrary); the terms “over” and “under” are expressly intended to identify a relative placement of structures (or layers, features, etc.), which expressly includes—but is not limited to—direct contact between the identified structures unless specifically identified as such. Similarly, the terms “over” and “under” are not limited to horizontal orientations, as a structure may be “over” a referenced structure if it is, at some point in time, an outermost portion of the construction under discussion, even if such structure extends vertically relative to the referenced structure, rather than in a horizontal orientation.

The terms “wafer” and “substrate” are used herein to refer generally to any structure on which integrated circuits are formed, and also to such structures during various stages of integrated circuit fabrication. The following detailed description is, therefore, not to be taken in a limiting sense, and the scope of the various embodiments is defined only by the appended claims, along with the full scope of equivalents to which such claims are entitled.

Various embodiments according to the present disclosure and described herein include memory utilizing a vertical structure of memory cells (e.g., NAND strings of memory cells). As used herein, directional adjectives will be taken relative a surface of a substrate upon which the memory cells are formed (i.e., a vertical structure will be taken as extending away from the substrate surface, a bottom end of the vertical structure will be taken as the end nearest the substrate surface and a top end of the vertical structure will be taken as the end farthest from the substrate surface).

As used herein, directional adjectives, such as horizontal, vertical, normal, parallel, perpendicular, etc., can refer to relative orientations, and are not intended to require strict adherence to specific geometric properties, unless otherwise noted. For example, as used herein, a vertical structure need not be strictly perpendicular to a surface of a substrate but may instead be generally perpendicular to the surface of the substrate, and may form an acute angle with the surface of the substrate (e.g., between 60 and 120 degrees, etc.).

In some embodiments described herein, different doping configurations may be applied to a select gate source (SGS), a control gate (CG), and a select gate drain (SGD), each of which, in this example, may be formed of or at least include polysilicon, with the result such that these tiers (e.g., polysilicon, etc.) may have different etch rates when exposed to an etching solution. For example, in a process of forming a monolithic pillar in a 3D semiconductor device, the SGS and the CG may form recesses, while the SGD may remain less recessed or even not recessed. These doping configurations may thus enable selective etching into the distinct tiers (e.g., SGS, CG, and SGD) in the 3D semiconductor device by using an etching solution (e.g., tetramethylammonium hydroxide (TMCH)).

According to one or more embodiments of the present disclosure, a memory controller (e.g., a processor, controller, firmware, etc.) located internal or external to a memory device, is capable of determining (e.g., selecting, setting, adjusting, computing, changing, clearing, communicating, adapting, deriving, defining, utilizing, modifying, applying, etc.) that a memory rank or memory bank is in a cold state (e.g., recording wear cycles, counting operations of the memory device as they occur, tracking the operations of the memory device it initiates, evaluating the memory device characteristics corresponding to a cold state, etc.)

According to one or more embodiments of the present disclosure, a memory access device may be configured to provide cold state information to the memory device with each memory operation. The memory device control circuitry (e.g., control logic) may be programmed to change the power mode of the memory rank or memory bank according to its cold state.

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can either be coupled, or directly coupled, unless otherwise indicated.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

Example 1 includes subject matter (such as a memory system) comprising multiple memory ranks and a memory controller. The memory ranks are comprised of multiple memory devices. The memory controller is configured to detect when time from a last access to a memory rank is greater than a first rank-access threshold time and place at least a portion of the memory rank in a first low power mode, and detect when time from a last access to a memory rank is greater than a second rank-access threshold time and place at least a portion of the memory rank in a second low power mode. The memory rank consumes lower energy in the first low power mode than a normal operating mode, and the memory rank consumes lower energy in the second low power mode than in the first low power mode.

In Example 2, the subject matter of Example 1 optionally includes memory devices that are dynamic random access memory (DRAM) devices, and the first low power mode is a self-refresh power down state and the second lower power mode is a deep sleep power state.

In Example 3, the subject matter of Example 2 optionally includes a memory controller configured to determine the time from the last access to the memory rank using a memory rank timer, reset the memory rank timer for the memory rank when the memory rank is accessed, set the memory rank to the self-refresh power down state when the memory rank timer exceeds the first rank-access threshold time, and set the memory rank to the deep sleep state when the memory rank timer exceeds the second rank-access threshold time.

In Example 4, the subject matter of one or both of Examples 2 and 3 optionally includes a memory controller configured to place a first portion of the multiple memory ranks of the memory system in the self-refresh power down state when detecting that the time from a last access to the memory ranks is greater than the first rank-access threshold time, change a second portion of multiple memory ranks of the memory system from the self-refresh power down state to the deep sleep state when detecting that the time from a last access to the second portion of memory ranks is greater than the second rank-access threshold time, and return operation of a memory rank of the first and second portions of the multiple memory ranks to a normal operating mode when detecting an access to the memory rank of the first and second portions of the multiple memory ranks.

In Example 5, the subject matter of one or any combination of Examples 1-4 optionally includes a memory controller configured to place only a memory bank of the memory rank in the first low power mode when time from a last access to the memory bank is greater than a first bank-access threshold time, and place only the memory bank of the memory rank in the second low power mode when the time from a last access to a memory bank is greater than a second bank-access threshold time.

In Example 6, the subject matter or Example 5 optionally includes each memory rank of the multiple memory ranks including multiple memory banks each having a bank number and memory banks with a same bank number are accessed in parallel in the multiple memory ranks, and optionally includes a memory controller configured to place all memory banks of the same bank number in the first low power mode when time from a last access to the memory banks of the same bank number is greater than the first bank-access threshold time, and change the memory banks of the same bank number from the first low power mode to the second low power mode when time from a last access to the memory banks of the same bank number is greater than the second bank-access threshold time.

In Example 7, the subject matter of Example 6 optionally includes the multiple memory devices being dynamic random access memory (DRAM) devices, and the first low power mode is a self-refresh power down state and the second lower power mode is a deep sleep power state, and optionally includes a memory controller configured to store a mapping of which memory banks of the multiple memory ranks are operating in the self-refresh power down state, in the deep sleep state, and in a normal operating state.

In Example 8, the subject matter of one or both of Examples 5 and 6 optionally includes the multiple memory devices being dynamic random access memory (DRAM) devices, and the first low power mode is a self-refresh power down state and the second lower power mode is a deep sleep power state, and optionally includes, and optionally includes a memory controller configured to determine the time from the last access to the memory bank using a memory bank timer, reset the memory bank timer for the memory bank when the memory bank is accessed, set the memory bank to the self-refresh power down state when the memory bank timer exceeds the first bank-access threshold time, and set the memory bank to the deep sleep state when the memory bank timer exceeds the second bank-access threshold time.

Example 9 includes subject matter (such as a method of operating a memory system) or can optionally be combined with one or any combination of Examples 1-8 to include such subject matter, comprising detecting when time from a last access to a memory rank of the memory system is greater than a first rank-access threshold time, and placing the memory rank in a first low power mode in response to the detecting, wherein the memory rank consumes lower energy in the first low power mode than a normal operating mode; and detecting when the time from a last access to a memory rank is greater than a second rank-access threshold time and placing the memory rank in a second low power mode, wherein the memory rank consumes lower energy in the second low power mode than in the first low power mode.

In Example 10, the subject matter of Example 9 optionally includes placing the memory rank in a self-refresh power down state in the first low power mode, and placing the memory rank in a deep sleep state in the second low power mode.

In Example 11, the subject matter of Example 10 optionally includes resetting a memory rank timer for the memory rank when the memory rank is accessed, setting the memory rank to the self-refresh power down state when the memory rank timer exceeds the first rank-access threshold time, and setting the memory rank to the deep sleep state when the memory rank timer exceeds the second rank-access threshold time.

In Example 12, the subject matter of one or both of Examples 10 and 11 optionally includes placing a first portion of multiple memory ranks of the memory system in the self-refresh power down state when detecting that the time from a last access to the memory ranks is greater than the first rank-access threshold time, placing a second portion of multiple memory ranks of the memory system in the deep sleep state when detecting that the time from a last access to the memory ranks is greater than the second rank-access threshold time, and operating a third portion of the multiple memory ranks in normal operating mode.

In Example 13, the subject matter of one or any combination of Examples 9-12 optionally includes detecting when time from a last access to a memory bank of the memory system is greater than a first bank-access threshold time, wherein the memory bank is included in a memory device of a memory rank of the memory system, placing the memory bank in the first low power mode in response to the detecting, detecting when the time from a last access to a memory bank is greater than a second bank-access threshold time, and placing the memory bank in the second low power mode.

In Example 14, the subject matter of Example 13 optionally includes detecting when time from a last access to a same memory bank of all the memory devices of a memory rank is greater than the first bank-access threshold time.

In Example 15, the subject matter of one or both of Examples 13 and 14 optionally includes resetting a memory bank timer for the memory bank when the memory bank is accessed, setting the memory bank to a self-refresh power down state when the memory bank timer exceeds the first bank-access threshold time, and setting the memory bank to a deep sleep state when the memory bank timer exceeds the second bank-access threshold time.

In Example 16, the subject matter of one or any combination of Examples 13-15 optionally includes placing a first portion of multiple memory banks of the memory system in a self-refresh power down state when detecting that the time from a last access to the memory banks is greater than the first rank-access threshold time, placing a second portion of the first portion of the multiple memory banks of the memory system in a deep sleep state when detecting that the time from a last access to the memory banks is greater than the second rank-access threshold time, and operating a third portion of the multiple memory banks in normal operating mode.

In Example 17, the subject matter of Example 16 optionally includes producing a memory map of which memory banks of the multiple memory banks are operating in the self-refresh power down state, in the deep sleep state, and in a normal operating state.

Example 18 includes subject matter (such as a memory controller device for a memory system) or can optionally be combined with one or any combination of Examples 1-17 to include such subject matter, comprising processing circuitry configured to reset a memory bank timer for a memory bank of the memory system when receiving a request to access the memory bank, place the memory bank in a self-refresh power down state when the memory bank timer exceeds a first bank-access threshold time, and place the memory bank in a deep sleep state when the memory bank timer exceeds a second bank-access threshold time.

In Example 19, the subject matter of Example 18 optionally includes processing circuitry configured to access the memory system according to memory ranks of the memory system, access a designated memory bank of each of the memory ranks in response to a request to access the designated memory bank, place the designated memory bank of each of the memory ranks in the self-refresh power down state when the memory bank timer exceeds a first bank-access threshold time, and place the designated memory bank of each of the memory ranks in the deep sleep state when the memory bank timer exceeds a second bank-access threshold time.

In Example 20, the subject matter of one or both of Examples 18 and 19 optionally includes processing circuitry configured to produce a mapping of which memory banks of multiple memory banks of the memory system are operating in the self-refresh power down state, in the deep sleep state, and in a normal operating state.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20.

Example 23 is a system to implement of any of Examples 1-20.

Example 24 is a method to implement of any of Examples 1-20.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A memory system comprising:
multiple memory ranks, wherein the memory ranks are comprised of multiple memory devices; and
a memory controller configured to:
detect when time from a last access to a memory rank is greater than a first rank-access threshold time and place at least a portion of the memory rank in a first low power mode, wherein the memory rank consumes lower energy in the first low power mode than a normal operating mode; and
detect when time from a last access to a memory rank is greater than a second rank-access threshold time and place at least a portion of the memory rank in a second low power mode, wherein the memory rank consumes lower energy in the second low power mode than in the first low power mode.

2. The system of claim 1, wherein the memory devices are dynamic random access memory (DRAM) devices, and the first low power mode is a self-refresh power down state and the second lower power mode is a deep sleep power state.

3. The system of claim 2, wherein the memory controller is configured to:
determine the time from the last access to the memory rank using a memory rank timer;
reset the memory rank timer for the memory rank when the memory rank is accessed;
set the memory rank to the self-refresh power down state when the memory rank timer exceeds the first rank-access threshold time; and
set the memory rank to the deep sleep state when the memory rank timer exceeds the second rank-access threshold time.

4. The system of claim 2, wherein the memory controller is configured to:
place a first portion of the multiple memory ranks of the memory system in the self-refresh power down state when detecting that the time from a last access to the memory ranks is greater than the first rank-access threshold time;
change a second portion of multiple memory ranks of the memory system from the self-refresh power down state to the deep sleep state when detecting that the time from a last access to the second portion of memory ranks is greater than the second rank-access threshold time; and
return operation of a memory rank of the first and second portions of the multiple memory ranks to a normal operating mode when detecting an access to the memory rank of the first and second portions of the multiple memory ranks.

5. The system of claim 1, wherein the memory controller is configured to:
place only a memory bank of the memory rank in the first low power mode when time from a last access to the memory bank is greater than a first bank-access threshold time; and
place only the memory bank of the memory rank in the second low power mode when the time from a last access to a memory bank is greater than a second bank-access threshold time.

6. The system of claim 5,
wherein each memory rank includes multiple memory banks each having a bank number and memory banks with a same bank number are accessed in parallel in the multiple memory ranks;
wherein the memory controller is configured to:
place all memory banks of the same bank number in the first low power mode when time from a last access to the memory banks of the same bank number is greater than the first bank-access threshold time; and
change the memory banks of the same bank number from the first low power mode to the second low power mode when time from a last access to the memory banks of the same bank number is greater than the second bank-access threshold time.

7. The system of claim 6,
wherein the memory devices are dynamic random access memory (DRAM) devices, and the first low power mode is a self-refresh power down state and the second lower power mode is a deep sleep power state; and
wherein the memory controller is configured to store a mapping of which memory banks of the multiple memory ranks are operating in the self-refresh power down state, in the deep sleep state, and in a normal operating state.

8. The system of claim 5,
wherein the memory devices are dynamic random access memory (DRAM) devices, and the first low power mode is a self-refresh power down state and the second lower power mode is a deep sleep power state;
wherein the memory controller is configured to:
determine the time from the last access to the memory bank using a memory bank timer;
reset the memory bank timer for the memory bank when the memory bank is accessed;
set the memory bank to the self-refresh power down state when the memory bank timer exceeds the first bank-access threshold time; and
set the memory bank to the deep sleep state when the memory bank timer exceeds the second bank-access threshold time.

9. A method of operating a memory system, the method comprising:
detecting when time from a last access to a memory rank of the memory system is greater than a first rank-access threshold time, and placing the memory rank in a first low power mode in response to the detecting, wherein the memory rank consumes lower energy in the first low power mode than a normal operating mode; and
detecting when the time from a last access to a memory rank is greater than a second rank-access threshold time and placing the memory rank in a second low power mode, wherein the memory rank consumes lower energy in the second low power mode than in the first low power mode.

10. The method of claim 9,
wherein placing the memory rank in the first low power mode includes placing the memory rank in a self-refresh power down state; and
wherein placing the memory rank in the second low power mode includes placing the memory rank in a deep sleep state.

11. The method of claim 10, including
resetting a memory rank timer for the memory rank when the memory rank is accessed;
setting the memory rank to the self-refresh power down state when the memory rank timer exceeds the first rank-access threshold time; and
setting the memory rank to the deep sleep state when the memory rank timer exceeds the second rank-access threshold time.

12. The method of claim 10, including:
placing a first portion of multiple memory ranks of the memory system in the self-refresh power down state when detecting that the time from a last access to the memory ranks is greater than the first rank-access threshold time;
placing a second portion of multiple memory ranks of the memory system in the deep sleep state when detecting that the time from a last access to the memory ranks is greater than the second rank-access threshold time; and
operating a third portion of the multiple memory ranks in normal operating mode.

13. The method of claim 9, including:
detecting when time from a last access to a memory bank of the memory system is greater than a first bank-access threshold time, wherein the memory bank is included in a memory device of a memory rank of the memory system;
placing the memory bank in the first low power mode in response to the detecting;
detecting when the time from a last access to a memory bank is greater than a second bank-access threshold time; and
placing the memory bank in the second low power mode.

14. The method of claim 13,
wherein detecting when time from a last access to a memory bank of the memory system is greater than the first bank-access threshold time includes detecting when time from a last access to a same memory bank of all the memory devices of a memory rank is greater than the first bank-access threshold time.

15. The method of claim 13, including
resetting a memory bank timer for the memory bank when the memory bank is accessed;
setting the memory bank to a self-refresh power down state when the memory bank timer exceeds the first bank-access threshold time; and
setting the memory bank to a deep sleep state when the memory bank timer exceeds the second bank-access threshold time.

16. The method of claim 13,
placing a first portion of multiple memory banks of the memory system in a self-refresh power down state when detecting that the time from a last access to the memory banks is greater than the first rank-access threshold time;
placing a second portion of the first portion of the multiple memory banks of the memory system in a deep sleep state when detecting that the time from a last access to the memory banks is greater than the second rank-access threshold time; and
operating a third portion of the multiple memory banks in normal operating mode.

17. The method of claim 16, including producing a memory map of which memory banks of the multiple memory banks are operating in the self-refresh power down state, in the deep sleep state, and in a normal operating state.

18. A memory controller device for a memory system, the device comprising:
processing circuitry configured to:
reset a memory bank timer for a memory bank of the memory system when receiving a request to access the memory bank;
place the memory bank in a self-refresh power down state when the memory bank timer exceeds a first bank-access threshold time; and
place the memory bank in a deep sleep state when the memory bank timer exceeds a second bank-access threshold time.

19. The device of claim 18, wherein the processing circuitry is configured to:
access the memory system according to memory ranks of the memory system;
access a designated memory bank of each of the memory ranks in response to a request to access the designated memory bank;
place the designated memory bank of each of the memory ranks in the self-refresh power down state when the memory bank timer exceeds a first bank-access threshold time; and
place the designated memory bank of each of the memory ranks in the deep sleep state when the memory bank timer exceeds a second bank-access threshold time.

20. The device of claim 18, wherein the processing circuitry is configured to:
produce a mapping of which memory banks of multiple memory banks of the memory system are operating in the self-refresh power down state, in the deep sleep state, and in a normal operating state.
